(19) United States
(12) Patent Application Publication
(10) Pub. No.: US 2025/0318122 A1
(43) Pub. Date: Oct. 9, 2025

(54) NON-VOLATILE MEMORY DEVICE

(71) Applicant: Samsung Electronics Co., Ltd., Suwon-si (KR)

(72) Inventors: Kangmin Kim, Suwon-si (KR); Sumin Lee, Suwon-si (KR); Eunsong Lee, Suwon-si (KR)

(21) Appl. No.: 18/929,803

(22) Filed: Oct. 29, 2024

(30) Foreign Application Priority Data
Apr. 8, 2024 (KR) 10-2024-0047365

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A non-volatile memory device includes a semiconductor substrate including a cell region, a dam region, and a stepped region. The non-volatile memory device includes a gate stack, a plurality of first channel structures, a dummy channel structure, a word line cut, at least one string select line, a plurality of second channel structures, a string select line cut, a buried structure, a dam structure, an oxide film that is on a sidewall of the word line cut and a bottom surface of the word line cut, a spacer liner that at least partially overlaps the oxide film, and a carbon layer that at least partially overlaps the spacer liner.

### CROSS-REFERENCE TO RELATED APPLICATION

This application is based on and claims priority under 35 U.S.C. § 119 to Korean Patent Application No. 10-2024-0047365, filed on Apr. 8, 2024, in the Korean Intellectual Property Office, the disclosure of which is incorporated by reference herein in its entirety.

### BACKGROUND

The present disclosure relates to a non-volatile memory device, and more particularly, to a 3-dimensional non-volatile vertical memory device including two structures bonded to each other.

Non-volatile memory devices with high performance, small size, and low price are being demanded. Therefore, to achieve a non-volatile memory device with a high degree of integration, a 3-dimensional non-volatile memory device in which a plurality of memory cells are arranged in a vertical direction has been proposed. Also, a non-volatile memory device formed by bonding a first structure including a portion of the non-volatile memory device and a second structure including another portion of the non-volatile memory device to each other has been proposed.

### SUMMARY

The present disclosure provides a non-volatile memory device that simplifies the manufacturing process and has operational reliability.

In addition, the technical goals to be achieved by the present disclosure are not limited to the technical goals mentioned above, and other technical goals may be clearly understood by one of ordinary skill in the art from the following descriptions.

According to an aspect of the present disclosure, there is provided non-volatile memory devices as follows.

According to an aspect of the present disclosure, there is provided a non-volatile memory device including a semiconductor substrate including a cell region, a dam region surrounding the cell region, and a stepped region between the cell region and the dam region. The non-volatile memory device includes a gate stack including a plurality of word line gate layers and a plurality of insulation layers that extend in a first direction that is parallel to an upper surface of the semiconductor substrate and are alternately stacked in a second direction that is perpendicular to the upper surface of the semiconductor substrate, where the gate stack has a stepped shape on the stepped region. The non-volatile memory device includes a plurality of first channel structures that are on the cell region and extend into the gate stack in the second direction. The non-volatile memory device includes a dummy channel structure that is on the stepped region and extends into the gate stack and in the second direction. The non-volatile memory device includes a word line cut that is on the cell region and extends into the gate stack in the second direction. The non-volatile memory device includes at least one string select line on the gate stack. The non-volatile memory device includes a plurality of second channel structures that extend into the at least one string select line from the plurality of first channel structures in the second direction. The non-volatile memory device includes a string select line cut that extends into the at least one string select line in the second direction. The non-volatile memory device includes a buried structure that is on the stepped region and extends in the second direction. The non-volatile memory device includes a dam structure that is on the dam region and extends in the second direction. The non-volatile memory device includes an oxide film that is on a sidewall of the word line cut and a bottom surface of the word line cut. The non-volatile memory device includes a spacer liner that at least partially overlaps the oxide film in the first direction and the second direction. The non-volatile memory device includes a carbon layer that at least partially overlaps the spacer liner in the first direction and the second direction.

According to another aspect of the present disclosure, there is provided a non-volatile memory device including a semiconductor substrate including a cell region, a stepped region adjacent to the cell region and having a stepped shape, and a dam region surrounding the cell region and the stepped region, a gate stack on the cell region. The non-volatile memory device includes a plurality of first channel structures that extend into the gate stack in a first direction that is perpendicular to an upper surface of the semiconductor substrate. The non-volatile memory device includes a word line cut that extends into the gate stack and extends in the first direction. The non-volatile memory device includes at least one string select line on the gate stack. The non-volatile memory device includes a plurality of second channel structures that extend into the at least one string select line from the plurality of first channel structures and extend in the first direction. The non-volatile memory device includes a string select line cut that extends into the at least one string select line and extends in a second direction that is parallel to the upper surface of the semiconductor substrate. The non-volatile memory device includes a dummy channel structure that is on the stepped region and extends in the first direction. The non-volatile memory device includes a buried structure that is spaced apart from the dummy channel structure in the second direction and extends parallel to the dummy channel structure. The non-volatile memory device includes a dam structure that is on the dam region and extends in the second direction. The non-volatile memory device includes an oxide film on sidewalls of the word line cut and a bottom surface of the word line cut. The non-volatile memory device includes a carbon layer that includes carbon (C) and at least partially overlaps the oxide film in the first direction and the second direction.

According to another aspect of the present disclosure, there is provided a non-volatile memory device including a semiconductor substrate including a cell region, a stepped region adjacent to the cell region, and a dam region surrounding the cell region and the stepped region. The non-volatile memory device includes a gate stack that is on the cell region and the stepped region and extends in a first direction that is parallel to a main surface of the semiconductor substrate, where the gate stack has a stepped shape on the stepped region. The non-volatile memory device includes a plurality of first channel structures that are on the cell region and extend into the gate stack in a second direction that is perpendicular to the main surface of the semiconductor substrate. The non-volatile memory device includes a word line cut that is spaced apart from the plurality of first channel structures in the first direction and extends in parallel with the plurality of first channel structures in the second direction. The non-volatile memory device includes at least one string select line on the gate stack. The non-volatile memory device includes a plurality of second channel structures that extend into the at least one string select line from the plurality of first channel structures in the second direction. The non-volatile memory device includes a string select line cut that extends into the at least one string select line in the first direction. The non-volatile memory device includes a dummy channel structure and a buried structure that extend into the gate stack on the stepped region in the second direction. The non-volatile memory device includes a dam structure that extends in the second direction and is on the dam region. The non-volatile memory device includes an oxide film that is on a sidewall of the word line cute and a bottom surface of the word line cut. The non-volatile memory device includes a carbon layer that is on the oxide film and in the word line cut, where the buried structure and the dam structure include a substantially same material, and where, relative to the main surface of the semiconductor substrate in the second direction, a first height of the buried structure and a second height of the dam structure are greater than a third height of the word line cut.

### BRIEF DESCRIPTION OF THE DRAWINGS

Embodiments of the present disclosure will be more clearly understood from the following detailed description taken in conjunction with the accompanying drawings in which:

FIG. 1 is a block diagram of a non-volatile memory device according to embodiments;

FIG. 2 is a schematic perspective view of a non-volatile memory device according to embodiments;

FIG. 3 is an equivalent circuit diagram of a memory cell array of a non-volatile memory device according to embodiments;

FIG. 4 is a plan view of components of a non-volatile memory device according to some embodiments;

FIGS. 5 to 16 are cross-sectional views showing a method of manufacturing a non-volatile memory device according to embodiments, according to the process sequence;

FIGS. 17 to 20 are cross-sectional views illustrating some of processes of a method of manufacturing a non-volatile memory device according to embodiments in detail;

FIGS. 21 and 22 are cross-sectional views of non-volatile memory devices according to other embodiments;

FIG. 23 is a configuration diagram showing an electronic system including a non-volatile memory device according to some embodiments;

FIG. 24 is a perspective view of an electronic system including a non-volatile memory device according to some embodiments; and

FIG. 25 is a cross-sectional view of a semiconductor package including a non-volatile memory device according to some embodiments.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and case of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

Hereinafter, example embodiments will be explained in detail with reference to the accompanying drawings.

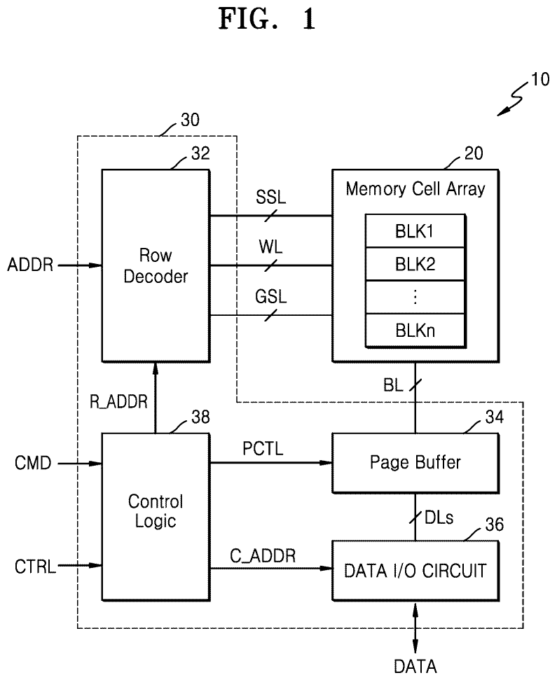

FIG. 1 is a block diagram of a non-volatile memory device according to embodiments.

Referring to FIG. 1, a non-volatile memory device 10 may include a memory cell array 20 and a peripheral circuit 30. The memory cell array 20 includes a plurality of memory cell blocks BLK1, BLK2, . . . , and BLKn. The memory cell blocks BLK1, BLK2, . . . , and BLKn may each include a plurality of memory cells. The memory cell blocks BLK1, BLK2, . . . , and BLKn may be connected to the peripheral circuit 30 through a bit line BL, a word line WL, a string select line SSL, and a ground select line GSL.

The peripheral circuit 30 may include a row decoder 32, a page buffer 34, a data input/output circuit 36, and a control logic 38. Although not shown in FIG. 1, the peripheral circuit 30 may further include an input/output interface, column logic, a voltage generator, a pre-decoder, a temperature sensor, a command decoder, an address decoder, an amplifier circuit, etc.

The memory cell array 20 may be connected to the page buffer 34 through the bit line BL, and the row decoder 32 may be connected to the row decoder 32 through the word line WL, the string select line SSL, and the ground select line GSL. In the memory cell array 20, the memory cells included in each of the memory cell blocks BLK1, BLK2, . . . , and BLKn may each be a flash memory cell. The memory cell array 20 may include a 3-dimensional memory cell array. The 3D memory cell array may include a plurality of NAND strings, and the NAND strings may each include a plurality of memory cells connected to a plurality of word lines WL vertically stacked on a substrate.

The peripheral circuit 30 may receive an address ADDR, a command CMD, and a control signal CTRL from a device outside the non-volatile memory device 10 and may transmit and receive data DATA to and from the device outside the non-volatile memory device 10.

The row decoder 32 may select at least one of the memory cell blocks BLK1, BLK2, . . . , and BLKn in response to an address ADDR from the outside and select the word line WL, the string select line SSL, and the ground select line GSL corresponding to a selected memory cell block. The row decoder 32 may transmit a voltage for performing a memory operation to the word line WL corresponding to the selected memory cell block.

The page buffer 34 may be connected to the memory cell array 20 through the bit line BL. The page buffer 34 may operate as a write driver during a program operation and apply a voltage according to the data DATA to be stored in the memory cell array 20 to the bit line BL and may operate as a sense amplifier during a read operation and sense the data DATA stored in the memory cell array 20. The page buffer 34 may operate according to a control signal PCTL provided from the control logic 38.

The data input/output circuit 36 may be connected to the page buffer 34 through data lines DLs. During a program operation, the data input/output circuit 36 may receive the data DATA from a memory controller (not shown) and provide the data DATA to be programmed to the page buffer 34 based on a column address C_ADDR provided from the control logic 38. The data input/output circuit 36 may provide the data DATA to be read, which is stored in the page buffer 34, to the memory controller based on the column address C_ADDR provided from the control logic 38 during a read operation.

The data input/output circuit 36 may transmit an address or a command input thereto to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide the column address C_ADDR to the data input/output circuit 36. The control logic 38 may generate various internal control signals used in the non-volatile memory device 10 in response to the control signal CTRL. For example, the control logic 38 may adjust the level of a voltage provided to the word line WL and the bit line BL when a memory operation like a program operation or an erase operation is performed.

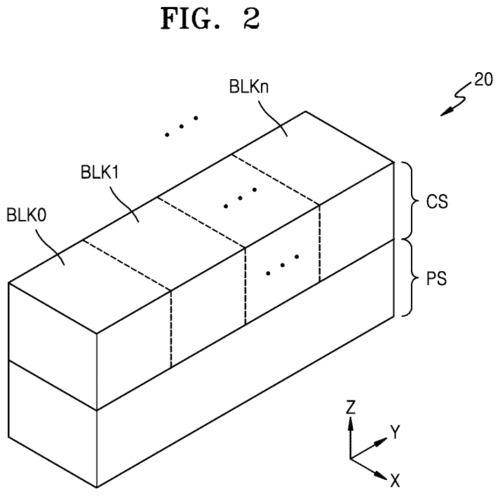

FIG. 2 is a schematic perspective view of a non-volatile memory device according to embodiments of the present disclosure.

Referring to FIG. 2, the non-volatile memory device 10 includes a cell array structure CS and a peripheral circuit structure PS overlapping each other in a vertical direction (Z direction). The cell array structure CS may include the memory cell array 20 described above with reference to FIG. 1. The peripheral circuit structure PS may include the peripheral circuit 30 described above with reference to FIG. 1.

The cell array structure CS may include the memory cell blocks BLK1, BLK2, . . . , and BLKn. The memory cell blocks BLK1, BLK2, . . . , and BLKn may each include 3-dimensionally arranged memory cells.

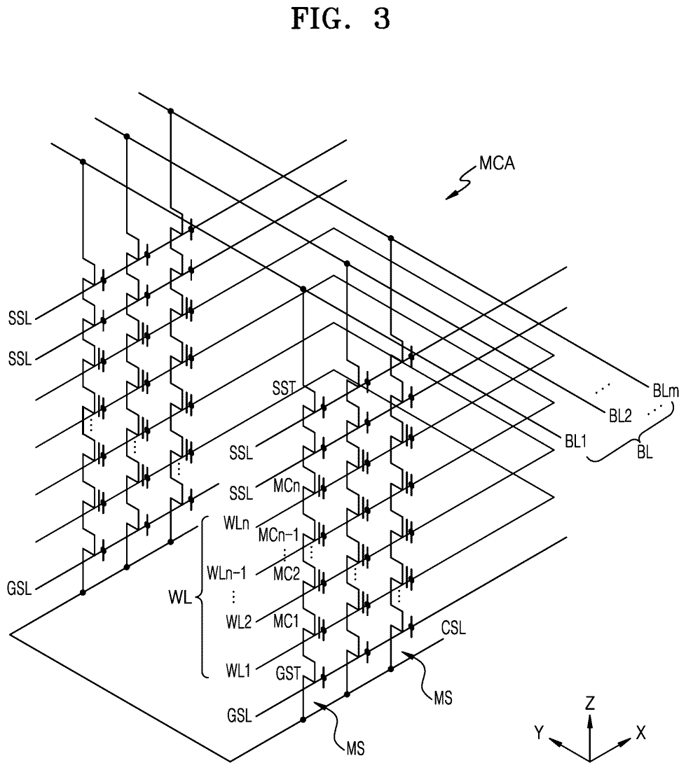

FIG. 3 is an equivalent circuit diagram of a memory cell array of a non-volatile memory device according to embodiments of the present disclosure.

Referring to FIG. 3, a memory cell array MCA may include a plurality of memory cell strings MS. The memory cell array MCA may include a plurality of bit lines BL: BL1, BL2, . . . , and BLm, a plurality of word lines WL: WL1, WL2, . . . , WLn-1, and WLn, at least one string select line SSL, at least one ground select line GSL, and a common source line CSL. The memory cell strings MS may be formed between the bit lines BL: BL1, BL2, . . . , and BLm and the common source line CSL. Although FIG. 3 shows a case in which the memory cell strings MS each include two string select lines SSL, the present disclosure is not limited thereto. For example, the memory cell strings MS may each include one string select line SSL.

The memory cell strings MS may each include the string select transistor SST, the ground select transistor GST, and a plurality of memory cell transistors MC1, MC2, . . . , MCn-1, and MCn. A drain region of the string select transistor SST may be connected to the bit lines BL: BL1, BL2, . . . , and BLm, and a source region of the ground select transistor GST may be connected to the common source line CSL. The common source line CSL may be a region in which source regions of a plurality of ground select transistors GST are connected in common.

The string select transistor SST may be connected to the string select line SSL, and the ground select transistor GST may be connected to the ground select line GSL. The memory cell transistors MC1, MC2, . . . , MCn-1, and MCn may be connected to the word lines WL: WL1, WL2, . . . , WLn-1, and WLn, respectively.

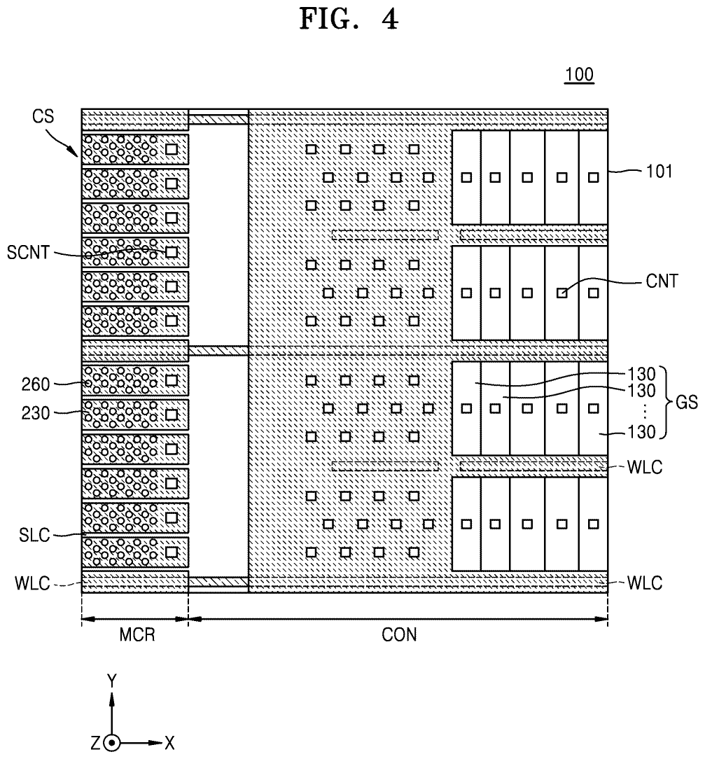

FIG. 4 is a plan view of components of a non-volatile memory device according to some embodiments.

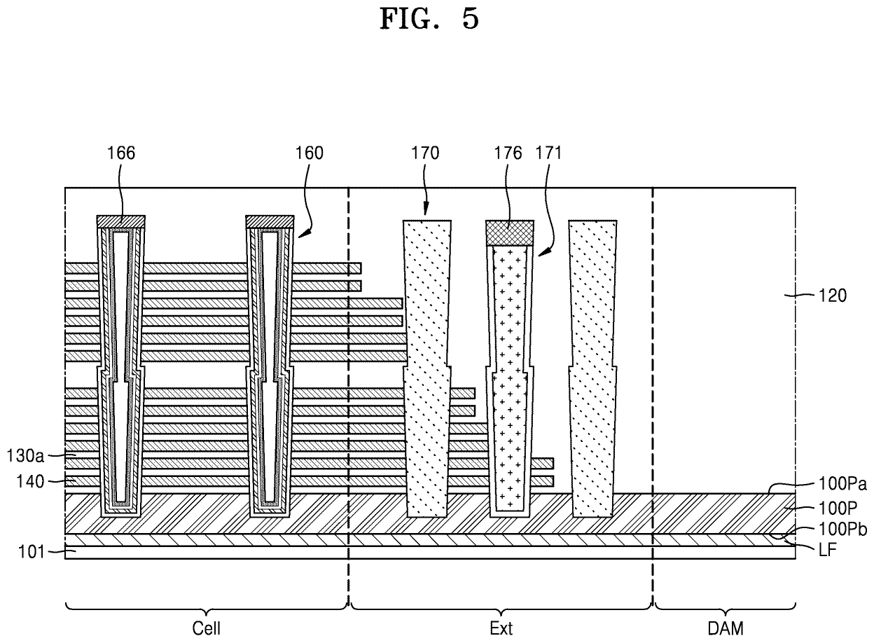

Referring to FIG. 4 together with FIGS. 5 to 16, a non-volatile memory device 100 may include a memory cell region MCR and a connection region CON.

The memory cell area MCR may be a region where the vertical channel structure NAND type memory cell array MCA described above with reference to FIG. 3 is formed. The connection region CON may be a region where pads for electrical connection between the memory cell array MCA formed in the memory cell region MCR and a peripheral circuit region (not shown) are formed.

A semiconductor substrate 101 may include a semiconductor material, e.g., a group IV semiconductor, a group III-V compound semiconductor, or a group II-VI oxide semiconductor. For example, a group IV semiconductor may include silicon (Si), germanium (Ge), or silicon-germanium (SiGe). The semiconductor substrate 101 may be provided as a bulk wafer or a wafer having an epitaxial layer formed thereon. According to some embodiments, the semiconductor substrate 101 may include a silicon-on-insulator (SOI) substrate or a germanium-on-insulator (GeOI) substrate.

A gate stack GS may extend on the semiconductor substrate 101 in a first direction (X direction) and a second direction (Y direction) that are parallel to the main surface of the semiconductor substrate 101. The gate stack GS may include a plurality of gate layers 130 and a plurality of insulation layers 140, and the plurality of gate layers 130 and the plurality of insulation layers 140 may be alternately arranged in a third direction (Z direction) that is perpendicular to the top or upper surface of the semiconductor substrate 101. Also, an upper insulation layer 150 may be disposed at the top of the gate stack GS.

The plurality of gate layers 130 may correspond to the ground select line GSL and the word line WL constituting a memory cell string MS described with reference to FIG. 3. For example, the lowermost gate layer 130 may function as the ground select line GSL and the remaining gate layers 130 may function as the word lines WL. Due to the function, the gate stack GS may also be referred to as a word line stack.

A plurality of word line cuts WLC may extend in first direction (X direction) on the semiconductor substrate 101. The gate stack GS disposed between a pair of word line cuts WLC may constitute one block, and the pair of word line cuts WLC may limit the width of the gate stack GS in the second direction (Y direction).

A plurality of first channel structures 160 may penetrate through or extend into the gate stack GS from the top surface of the semiconductor substrate 101 and extend in the third direction (Z direction), in the memory cell region MCR. The plurality of first channel structures 160 may be arranged to be spaced apart from one another at certain intervals in the first direction (X direction) and the second direction (Y direction). The plurality of first channel structures 160 may be arranged in a zigzag shape or staggered shape. According to some embodiments, the level of the top or uppermost surface of the plurality of first channel structures 160 in the Z direction relative to the upper surface of the substrate 101 and the level of the top or uppermost surface of the word line cut WLC in the Z direction relative to the upper surface of the substrate 101 may be substantially the same.

The plurality of first channel structures 160 may be formed to penetrate through or extend into the gate stack GS. The plurality of first channel structures 160 may each include a gate insulation layer (not shown), a channel layer (not shown), a filling insulation layer (not shown), and a channel pad 166. The gate insulation layer and the channel layer may be sequentially arranged on the sidewalls of the plurality of first channel structures 160. For example, the gate insulation layer may be conformally disposed on the sidewall of a first channel structure 160, and the channel layer may be conformally disposed on the sidewall and bottom surface of the first channel structure 160. The filling insulation layer that fills or is in the remaining space of the first channel structure 160 may be disposed on the channel layer. The channel pad 166, which contacts the channel layer and blocks or overlaps at least a portion of the entrance (e.g., the top end) of the first channel structure 160 in the Z direction, may be disposed over the first channel structure 160.

According to some embodiments, a contact semiconductor layer having a certain height may be formed on the semiconductor substrate 101 at the bottom of the plurality of first channel structures 160, and the channel layer may be electrically connected to the semiconductor substrate 101 through the contact semiconductor layer. The contact semiconductor layer will be described in detail later with reference to FIG. 5.

The gate insulation layer may have a structure that sequentially includes a tunneling dielectric layer, a charge storage layer, and a blocking dielectric layer on the outer wall of the channel layer. The relative thicknesses of the tunneling dielectric layer, charge storage layer, and blocking dielectric layer constituting the gate insulation layer are not particularly limited and various modifications may be made therein.

The tunneling dielectric layer may include silicon oxide, hafnium oxide, aluminum oxide, zirconium oxide, tantalum oxide, etc. The charge storage layer is a region in which electrons that passed through the tunneling dielectric layer from the channel region layer may be stored and may include silicon nitride, boron nitride, silicon boron nitride, or polysilicon doped with impurities. The blocking dielectric layer may include silicon oxide, silicon nitride, or a metal oxide having a higher permittivity than silicon oxide.

A string select line stack SS may be disposed on top of the gate stack GS over the semiconductor substrate 101. The string select line stack SS may include at least one second gate layer 230 and at least one second insulation layer 240, and the at least one second gate layers 230 and second insulation layers 240 may be alternately arranged in the third direction (Z direction) that is perpendicular to the top surface of the semiconductor substrate 101. Also, a second upper insulation layer 250 may be disposed on top of the string select line stack SS.

The second gate layer 230 may include a second buried conductive layer (not shown) and a second insulation liner (not shown) surrounding at least a portion of the top surface, the bottom surface, and the side surfaces of the second buried conductive layer. According to some embodiments, the second gate layer 230 may include a polysilicon monolayer structure, an oxide/polysilicon stack structure, or an oxide/metal stack structure, but the present disclosure is not limited thereto.

A plurality of second channel structures 260 may penetrate through or extend into the string select line stack SS and extend in the third direction (Z direction). The plurality of second channel structures 260 may be arranged to be spaced apart from one another at certain intervals in the first direction (X direction) and the second direction (Y direction). The plurality of second channel structures 260 may be arranged in a zigzag shape or staggered shape. The plurality of second channel structures 260 may be arranged to be electrically connected to the plurality of first channel structures 160 through connection vias 260V.

The plurality of second channel structures 260 may be formed to penetrate through or extend into the string select line stack SS. The plurality of second channel structures 260 may each include a second gate insulation layer (not shown), a second channel layer (not shown), a second filling insulation layer (not shown), and a second conductive plug (not shown).

Here, a first distance between adjacent ones of the plurality of first channel structures 160 may be smaller than a second distance between adjacent ones of the plurality of second channel structures 260 with a string select line cut SLC therebetween. Since the string select line cut SLC is disposed between the plurality of second channel structures 260, adjacent ones of the plurality of second channel structures 260 may be arranged at the second distance to be sufficiently spaced apart from each other.

In the memory cell region MCR, a plurality of string select line cuts SLC penetrating through or that extend into the string select line stack SS and in the third direction (Z direction) may be disposed. The plurality of string select line cuts SLC may include an insulation structure 270.

According to some embodiments, the word line cut WLC may have an inverted trapezoidal shape whose horizontal width (e.g., a width in the X direction) decreases in a direction toward the main or upper surface of the semiconductor substrate 101.

Referring back to FIG. 4 together with FIGS. 5 to 16, the contact plug CNT that penetrates through or extends into a cover insulation layer 120 in the connection region CON and is connected to a pad PAD of the gate layer 130 may be disposed. The contact plug CNT may have a tapered pillar-like shape whose width decreases downwardly in the third direction (Z direction) (e.g., in the Z-direction toward the upper surface of the semiconductor substrate 101). According to some embodiments, a second contact plug SCNT connected to the second gate layer 230 in the memory cell region MCR may be disposed to correspond to the contact plug CNT. The connection region CON shown in FIG. 4 may include a stepped region EXT shown in FIG. 5.

FIGS. 5 to 16 are cross-sectional views showing a method of manufacturing a non-volatile memory device according to embodiments, according to the process sequence.

Referring to FIG. 5, a liner film LF may be formed on the semiconductor substrate 101 including a cell region CELL, a stepped region EXT, and a dam region DAM. The liner film LF may include titanium nitride (TiN), but is not limited thereto. A pre-cell substrate 100P may be formed on the liner film LF. The pre-cell substrate 100P may include a front surface 100Pa and a back surface 100Pb that are opposite to each other. The back surface 100Pb of the pre-cell substrate 100P may face the substrate 101. The pre-cell substrate 100P may include polysilicon.

A plurality of mold sacrificial layers 130a and the plurality of insulation layers 140 may be alternately stacked on the front surface 100Pa of the pre-cell substrate 100P. The mold sacrificial layers 130a and the insulation layers 140 may be stacked in a stepped shape. The mold sacrificial layers 130a may each include a material having an etch selectivity with respect to each insulation layer 140. For example, when the insulation layer 140 includes silicon oxide, a mold sacrificial layer 130a may include silicon nitride. The stacked structure formed by the plurality of mold sacrificial layers 130a and the insulation layer 140 may be formed to have a stepped shape in the stepped region EXT and may not be formed on the dam region DAM.

In the cell region CELL, the plurality of first channel structures 160 penetrating through or extending into the mold sacrificial layer 130a and the insulation layer 140 may be formed. Channel pads 166 may be formed on the plurality of first channel structures 160. In the stepped region EXT, a dummy channel structure 170 and an insulation structure 171 extending parallel to the plurality of first channel structures 160 may be formed. An insulation pad 176 may be formed on the insulation structure 171.

The cover insulation layer 120 may be formed on the cell region CELL, the stepped region EXT, and the dam region DAM. The cover insulation layer 120 may be formed to have a thickness sufficient to cover or overlap the entire upper portions of the plurality of first channel structures 160, the dummy channel structure 170, and the insulation structure 171 in the Z direction.

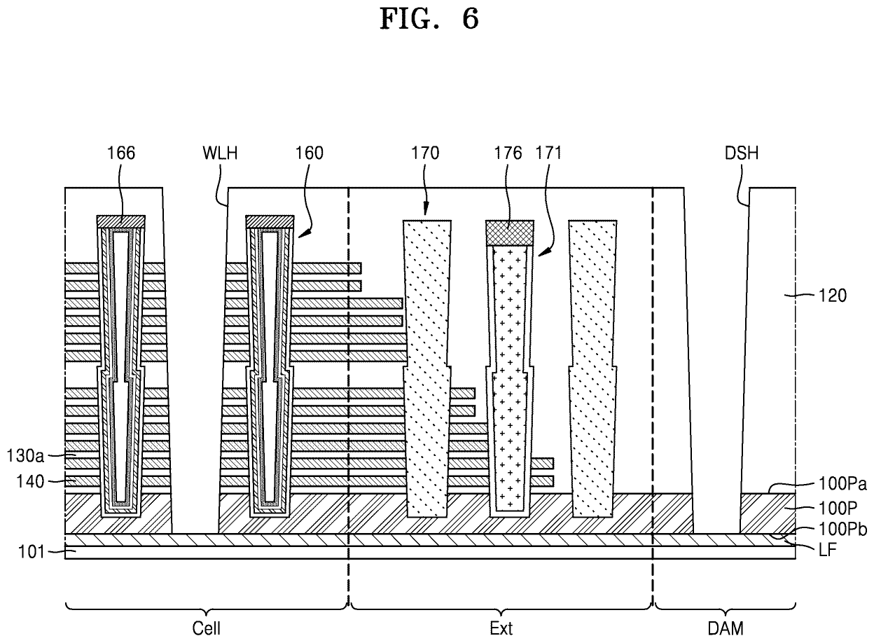

Referring to FIG. 6, a word line opening WLH may be formed by removing portions of the plurality of mold sacrificial layers 130a and the plurality of insulation layers 140 in the cell region CELL. Through the same process, a portion of the cover insulation layer 120 may be etched in the dam region DAM, thereby forming a dam structure opening DSH. The process of forming the word line opening WLH and the process of forming the dam structure opening DSH may also be performed simultaneously. Both the word line opening WLH and the dam structure opening DSH may have an inverted trapezoidal shape whose horizontal width decreases in a direction toward the main or upper surface of the semiconductor substrate 101.

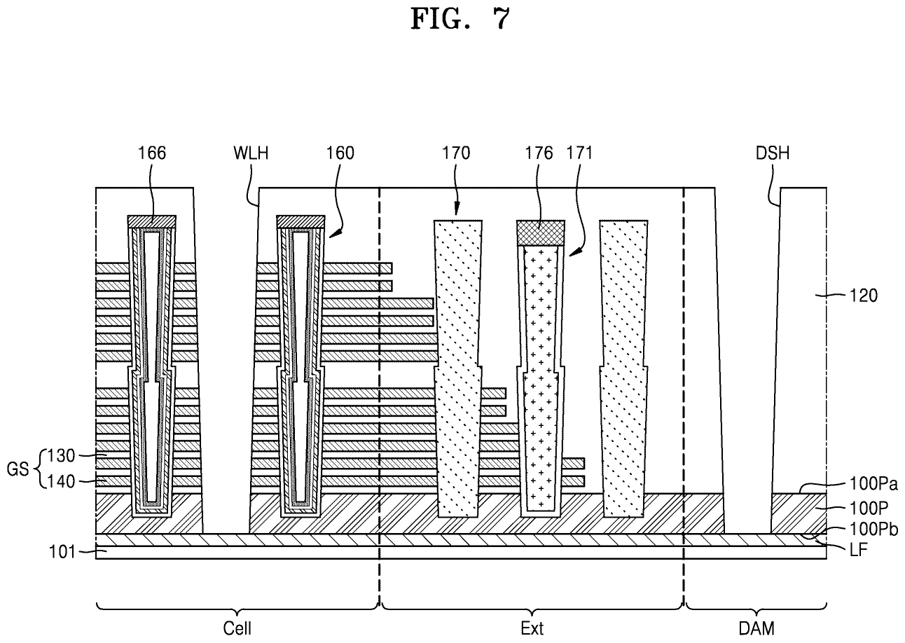

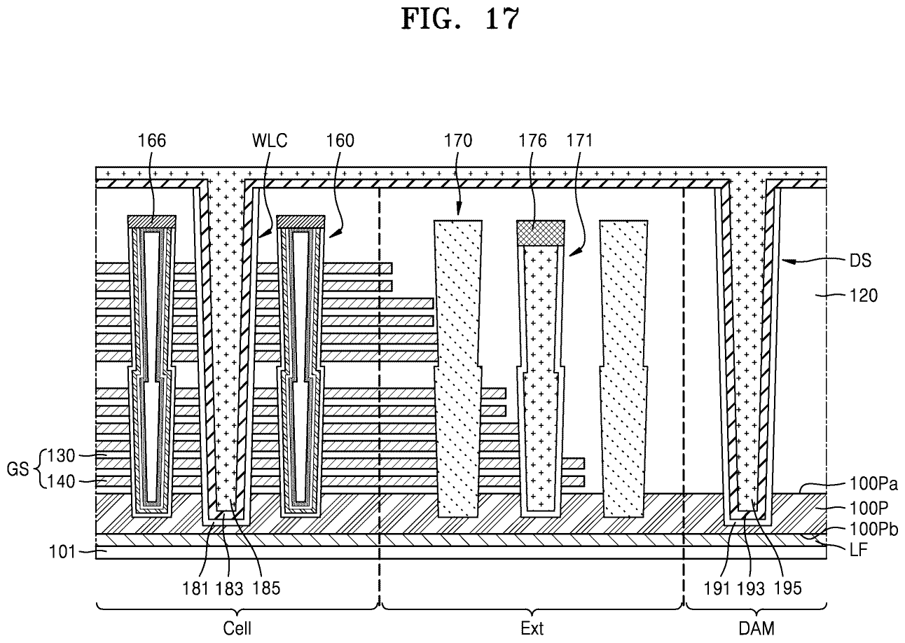

Referring to FIG. 7, the plurality of mold sacrificial layers 130a (refer to FIG. 6) formed across the cell region CELL and the stepped region EXT may be removed, and a conductive material may be buried in the space formed by removing the plurality of mold sacrificial layers 130a, thereby forming the plurality of gate layers 130. In other words, a replacement process may be performed to form the plurality of gate layers 130 by replacing the plurality of mold sacrificial layers 130a (refer to FIG. 6) with a conductive material. As a result of the replacement process, the gate stack GS including the plurality of gate layers 130 and the plurality of insulation layers 140 may be obtained. Additional details regarding the steps illustrated in FIG. 7 are provided below with reference to FIGS. 17-20.

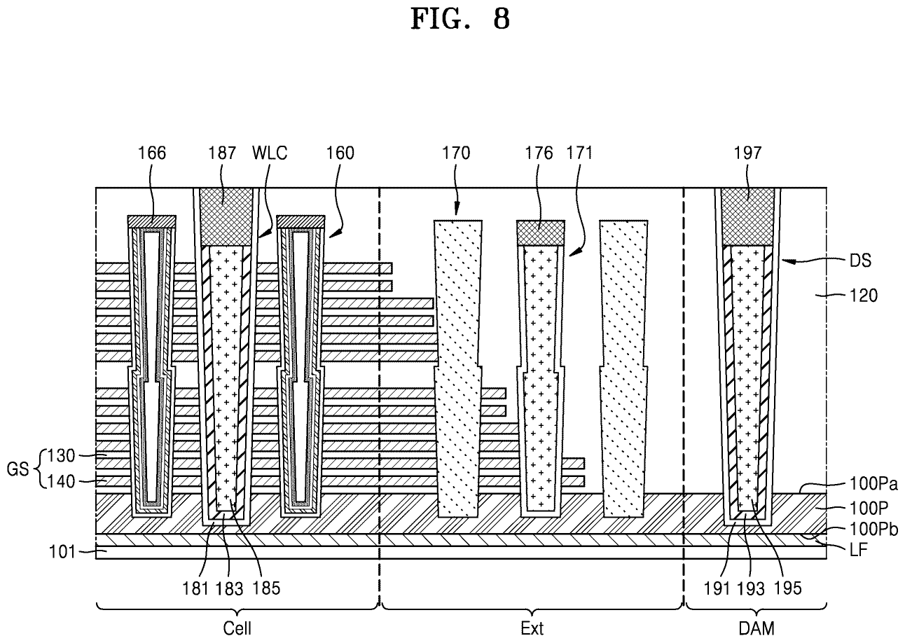

Referring to FIG. 8, the word line cut WLC and a dam structure DS respectively filling or in the word line opening WLH of the cell region CELL and the dam structure opening DSH of the dam region DAM may be formed. Additional details regarding the steps illustrated in FIG. 8 are provided below with reference to FIGS. 17-20.

An oxide film 181 and a spacer liner 183 may be sequentially arranged on the sidewall of the word line cut WLC. For example, the oxide film 181 may be conformally disposed on the sidewall and the bottom surface of the word line cut WLC (e.g., the oxide film 181 at least partially overlaps the sidewall of the word line cut WLC in the X direction and at least partially overlaps the bottom surface of the word line cut WLC in the Z direction), and the spacer liner 183 may conformally cover or overlap the oxide film 181 (e.g., the spacer liner 183 at least partially overlaps the oxide film 181 in the X direction and at least partially overlaps the oxide film 181 in the Z direction). A carbon layer 185 that fills or is in the remaining space of the word line cut WLC may be disposed on the spacer liner 183 (e.g., the carbon layer 185 at least partially overlaps the spacer liner 183 in the X direction and at least partially overlaps the spacer liner 183 in the Z direction). A word line cut pad 187 may be disposed above the word line cut WLC to block or at least partially overlap the entrance (e.g., the top end) of the word line cut WLC in the Z direction.

According to embodiments, the spacer liner 183 may be configured to include at least one of polysilicon, titanium nitride (TiN), and tungsten (W). According to some embodiments, the thickness of spacer liner 183 may be 15 nm or greater in the X direction and/or the Z direction. According to some embodiments, the thickness of spacer liner 183 may not exceed 50 nm in the X direction and/or the Z direction.

According to embodiments, the carbon layer 185 may include only pure carbon (C). However, the present disclosure is not limited thereto, and the carbon layer 185 may include a C-containing material.

A dam oxide film 191 and a dam spacer liner 193 may be sequentially arranged on the sidewall of the dam structure DS. For example, the dam oxide film 191 may be conformally disposed on the sidewall and the bottom surface of the dam structure DS, and the dam spacer liner 193 may conformally cover or overlap the dam oxide film 191. A dam carbon layer 195 that fills or is in the remaining space of the dam structure DS may be disposed on the dam spacer liner 193. A dam structure pad 197 may be disposed over the dam structure DS to block or at least partially overlap the entrance (e.g., the top) of the dam structure DS in the Z direction.

According to embodiments, the dam oxide film 191 may include substantially the same material as the oxide film 181 and may be formed through the same process. According to embodiments, the dam spacer liner 193 may include substantially the same material as the spacer liner 183 and may be formed through the same process. According to embodiments, the dam carbon layer 195 may include substantially the same material as the carbon layer 185 and may be formed through the same process.

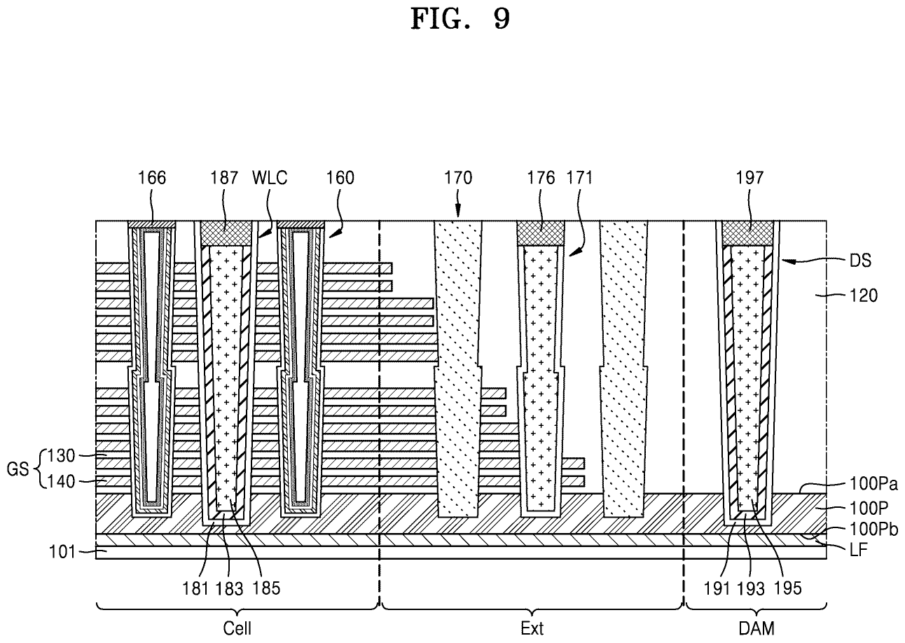

Referring to FIG. 9, portions of the cover insulation layer 120 arranged on the cell region CELL, the stepped region EXT, and the dam region DAM may be polished until the top surfaces of the plurality of first channel structures 160 are exposed. In the above-stated process, the upper portion of the word line cut WLC and the upper portion of the dam structure DS may be partially polished together. In other words, the thickness of the word line cut pad 187 and the dam structure pad 197 in the Z direction may be partially reduced.

The polishing process may be an etch-back process or a chemical mechanical polishing (CMP) process. Through the polishing process, the level of the top surface of the plurality of first channel structures 160 relative to the upper surface of the substrate 101 in the Z direction may be formed to be substantially identical to the level of the top surface of the word line cut WLC and the level of the top surface of the dam structure DS relative to the upper surface of the substrate 101 in the Z direction.

According to embodiments, the vertical thickness (e.g., the thickness in the Z direction) of the word line cut pad 187 may be from about 100 nm to about 1000 nm.

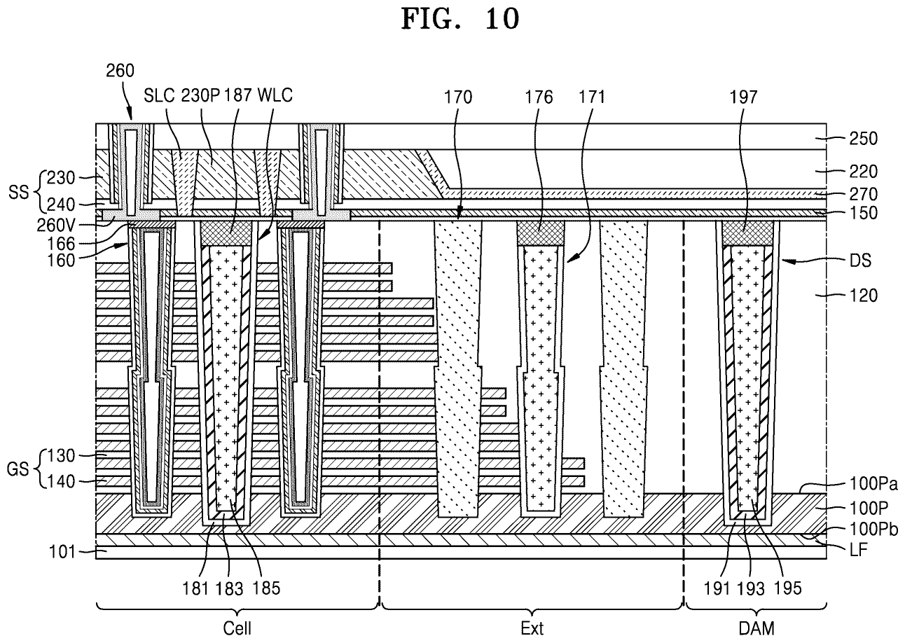

Referring to FIG. 10, a string select line SS in which at least one second gate layer 230 and at least one second insulation layer 240 are stacked may be formed on a polished surface.

The at least one second gate layer 230 may be formed as a single layer structure of polysilicon, a stacked structure of an oxide/polysilicon, or a stacked structure of an oxide/a metal, but is not limited thereto. Also, the at least one second insulation layer 240 may include silicon oxide, but is not limited thereto.

Next, a portion of the second gate layer 230 may be removed, and the string select line cut SLC defining a cover structure 230P may be formed on the word line cut WLC.

In the cell region CELL, the plurality of string select line cuts SLC penetrating through or extending into the string select line stack SS and in the first direction (X direction) may be formed. The plurality of string select line cuts SLC may be formed of the insulation structure 270.

Due to the process of forming the string select line cuts SLC, the word line cut WLC may have an inverted trapezoidal shape whose horizontal width decreases in a direction toward the main or upper surface of the semiconductor substrate 101 in the Z direction, and the cover structure 230P disposed over the word line cut WLC to overlap the word line cut WLC may extend in the first direction (X direction) and have a trapezoidal shape whose horizontal width increases in a direction toward the main or upper surface of the semiconductor substrate 101 in the Z direction.

The cover structure 230P may be formed between the string select line cuts SLC that are next or adjacent to each other. In other words, the cover structure 230P may be a region defined by the string select line cuts SLC.

Referring to FIG. 10, next, a plurality of second channel holes (not shown) penetrating through or extending into the string select line stack SS are formed, and then a plurality of second channel structures 260 filling or in the plurality of second channel holes may be formed.

The plurality of second channel structures 260 may be formed to penetrate through or extend into the string select line stack SS and in the third direction (Z direction). The plurality of second channel structures 260 may be arranged in a zigzag shape or staggered shape. The plurality of second channel structures 260 may be formed to be electrically connected to the plurality of first channel structures 160 through connection vias 260V.

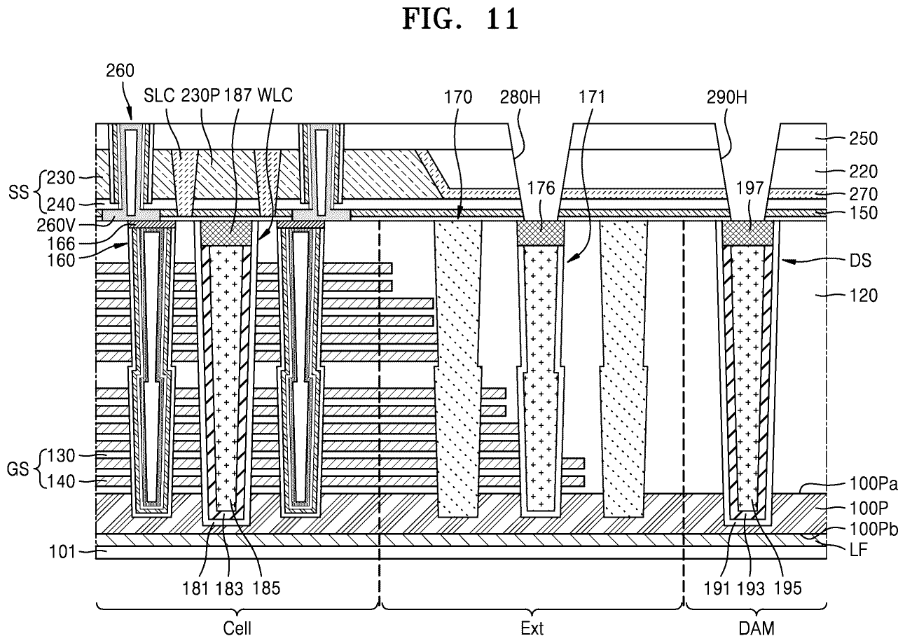

Referring to FIG. 11, a buried structure hole 280H and a second dam structure hole 290H may be formed on the stepped region EXT and the dam region DAM, respectively. The buried structure hole 280H and the second dam structure hole 290H may each be formed to penetrate through or extend into the second upper insulation layer 250, a second cover insulation layer 220, the insulation structure 270, and the second insulation layer 240 and have an inverted trapezoidal shape whose horizontal width decreases in a direction toward the main or upper surface of the semiconductor substrate 101 in the Z direction.

According to some embodiments, the buried structure hole 280H may be formed on the insulation pad 176 of the insulation structure 171 to overlap at least a portion of the insulation structure 171 in the third direction (Z direction) that is perpendicular to the semiconductor substrate 101. According to some embodiments, the second dam structure hole 290H may be formed on the dam structure pad 197 of the dam structure DS to overlap at least a portion of the dam structure DS in the third direction (Z direction) that is perpendicular to the semiconductor substrate 101. In some embodiments, the top surfaces of the insulation pad 176 and the dam structure pad 197 may be exposed by the buried structure hole 280H and the second dam structure hole 290H.

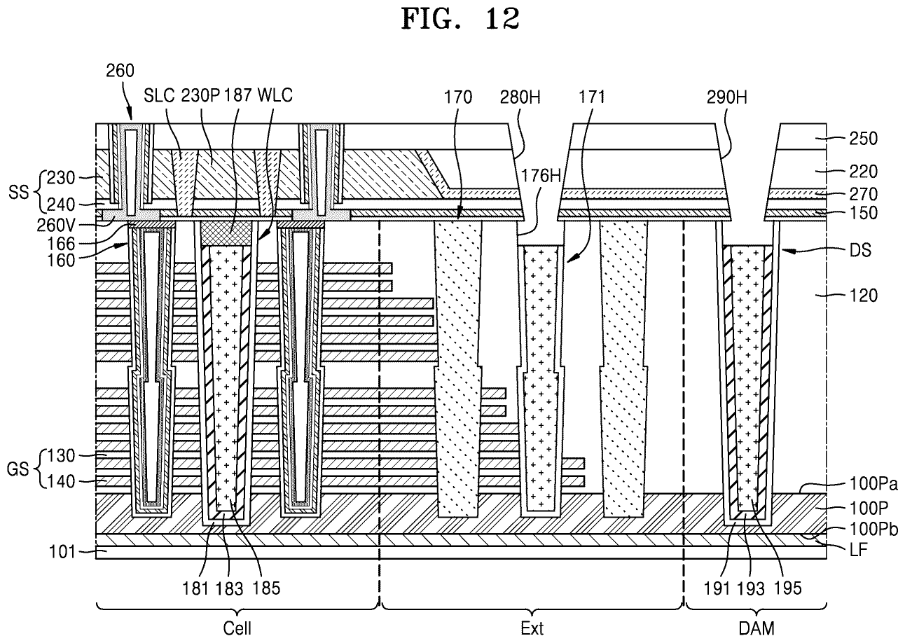

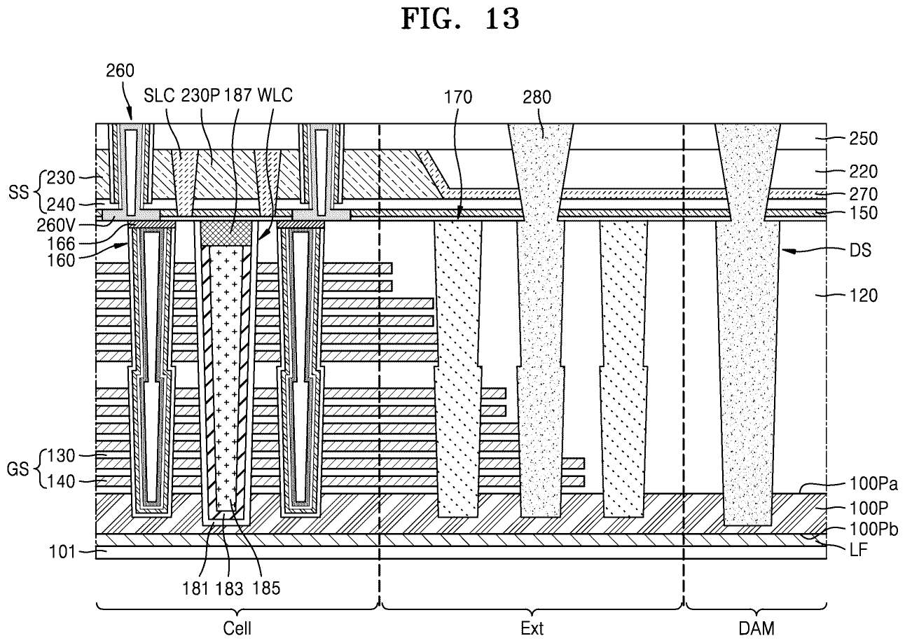

Referring to FIGS. 12 and 13 together, the insulation structure 171 and the dam structure DS may be exposed by removing the insulation pad 176 and the dam structure pad 197. Next, the materials included in the insulation structure 171 and the dam structure DS may be removed and a buried structure 280 and the dam structure DS filled with or including a metal may be obtained.

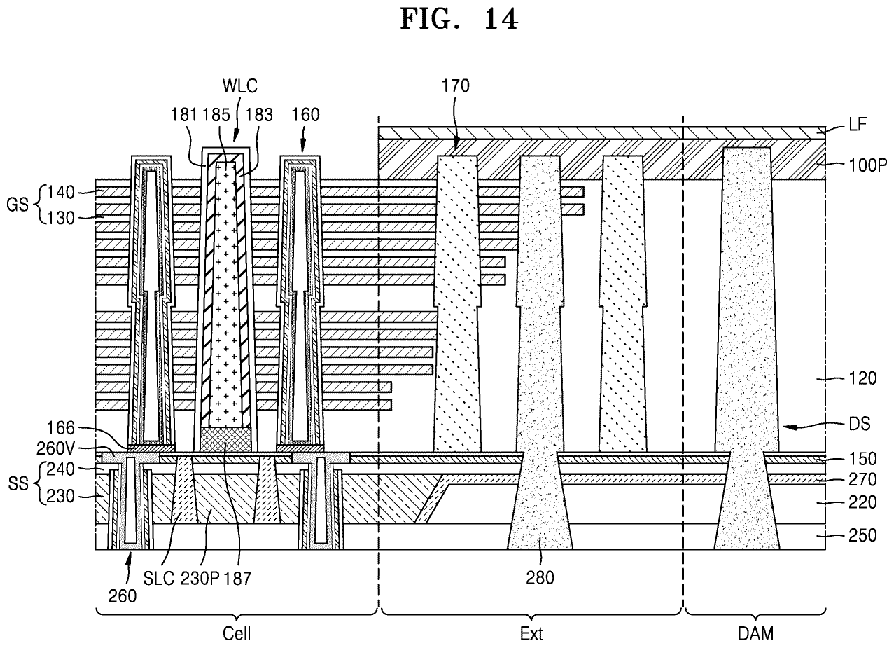

Referring to FIG. 14, a chip-to-chip bonding process for connecting an upper chip including the memory cell array structure CS (refer to FIG. 2) and a lower chip including the peripheral circuit structure PS (refer to FIG. 2) to each other through bonding may be performed. In FIG. 14, only the upper chip is shown for convenience of illustration. A result structure of FIG. 13 may be turned upside down through the above-stated process. The semiconductor substrate 101 may be removed through a grinding process or an etching process, and the liner film LF and the pre-cell substrate 100P on the cell region CELL may also be removed. In other words, the word line cuts WLC and upper portions of the plurality of first channel structures 160 may be exposed.

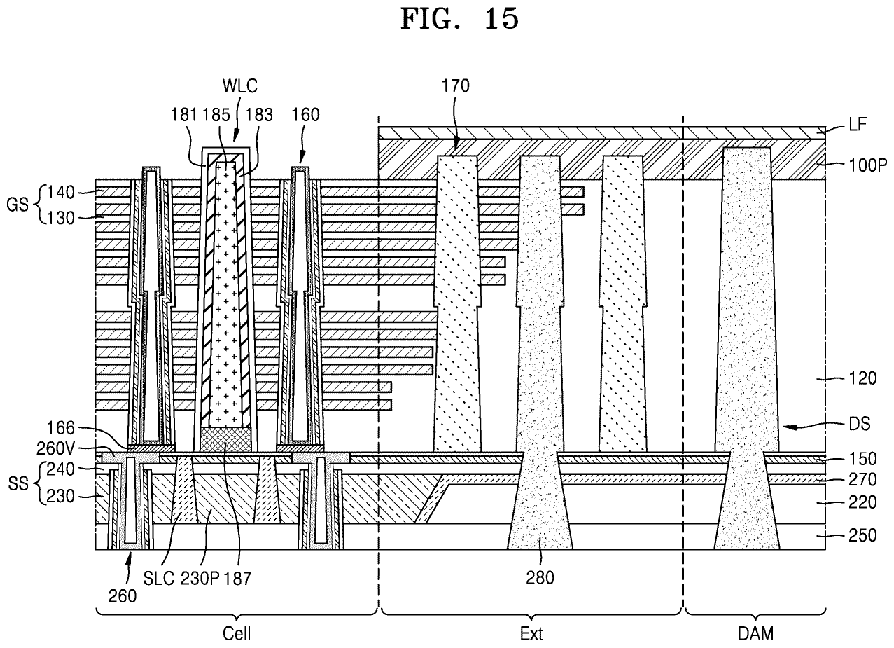

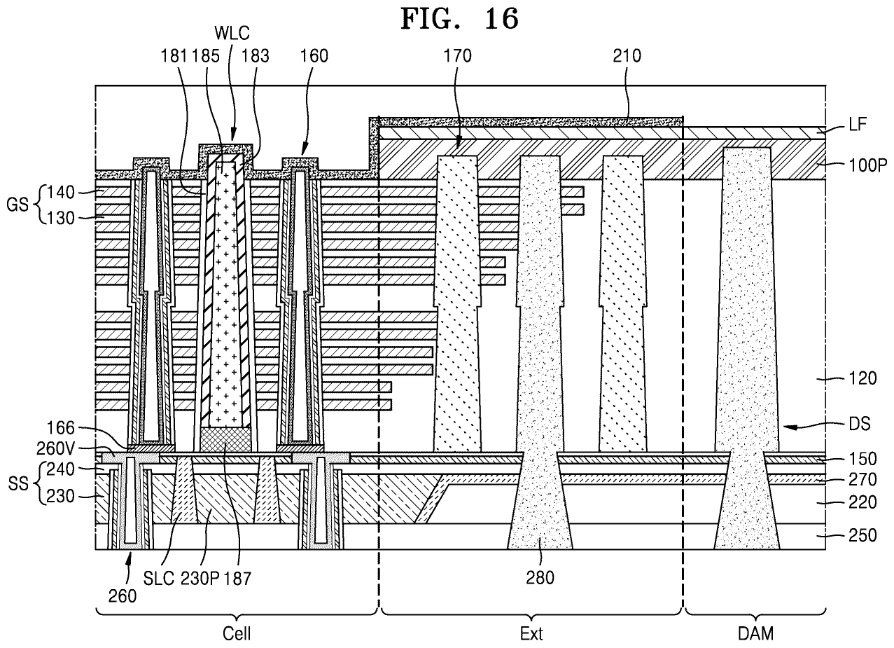

Referring to FIGS. 15 and 16, an etching process may be performed on the word line cuts WLC and the plurality of first channel structures 160 of FIG. 14. According to embodiments, portions of exposed gate insulation layers of the plurality of first channel structures 160 may be removed through an etching process to expose the top surface of the channel layer. According to embodiments, a portion of the oxide film 181 of the word line cut WLC may be removed through an etching process to expose the top surface and the sidewalls of the spacer liner 183.

Referring to FIG. 16, a common source line 210 conformally covering or overlapping the cell region CELL and the stepped region EXT may be formed. The common source line 210 shown in FIG. 16 may be a component corresponding to the common source line CSL of FIG. 3. The common source line 210 may conformally cover or overlap the exposed top surfaces and the exposed side surfaces of the first channel structure 160 and the word line cut WLC of the cell region CELL. Also, since the common source line 210 is formed on a relatively flat top surface of the liner film LF in the stepped region EXT, the common source line layer 210 may be formed to have a relatively flat top surface level.

Afterwards, a laser annealing process may be performed on the common source line 210. According to embodiments, the laser annealing process may be performed to improve the crystallinity of the common source line 210, increase the grain size of the common source line 210, or reduce the resistance of the common source line 210. Afterwards, subsequent processes for manufacturing a non-volatile memory device may be performed.

FIGS. 17 to 20 are cross-sectional views illustrating some of processes of a method of manufacturing a non-volatile memory device according to embodiments in detail.

More particularly, FIGS. 17 to 20 may be additional descriptions of the processes shown in FIGS. 7 and 8.

First, referring to FIG. 17, in a result structure of FIG. 7, the oxide film 181 and the dam oxide film 191 may be first formed on the sidewalls and the bottom surfaces of the word line opening WLH and the dam structure opening DSH. According to some embodiments, the oxide film 181 and the dam oxide film 191 may include substantially the same material. Next, along the top surfaces of the oxide film 181 formed over or on the word line opening WLH, the dam oxide film 191 formed over or on the dam structure opening DSH, and the cover insulation layer 120, the spacer liner 183 having a conformal thickness may be deposited. According to embodiments, the spacer liner 183 may be configured to include at least one of polysilicon, TiN, and W. According to some embodiments, the thickness of the spacer liner 183 may be from about 15 nm to about 50 nm in the X direction and/or the Z direction.

Finally, the carbon layer 185 covering or on the remaining spaces of the word line opening WLH and the dam structure opening DSH and the top surface of the spacer liner 183 may be formed over the same. According to embodiments, the carbon layer 185 may include only pure carbon (C). However, the present disclosure is not limited thereto, and the carbon layer 185 may include a C-containing material.

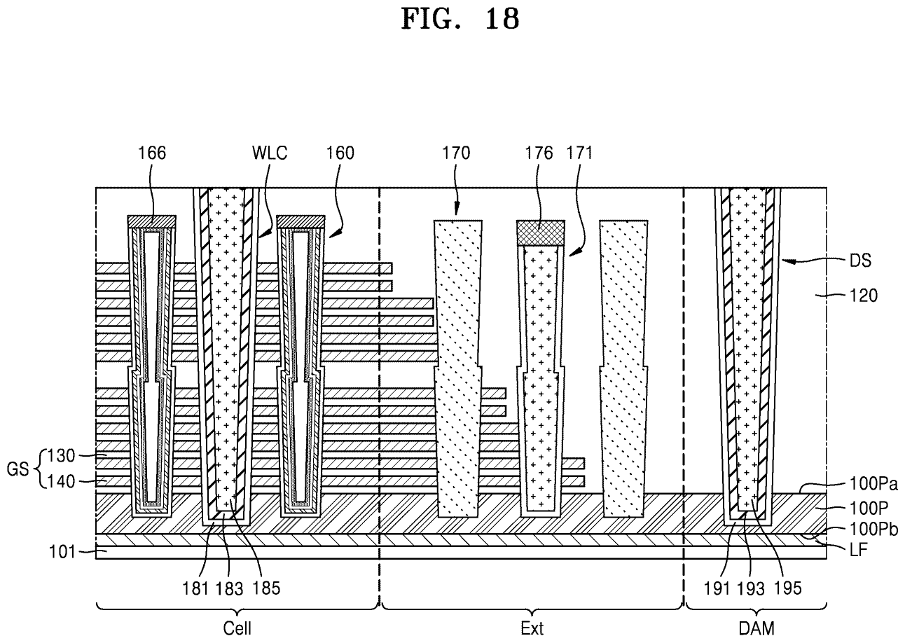

Next, referring to FIG. 18, a polishing process may be performed until stacked portions of the spacer liner 183 and the carbon layer 185 extending on the cell region CELL, the stepped region EXT, and the dam region DAM in a direction parallel to the semiconductor substrate 101 are removed. In other words, the polishing process may be performed until the top surface of the cover insulation layer 120 is exposed. At this time, the polishing process may be chemical mechanical polishing (CMP).

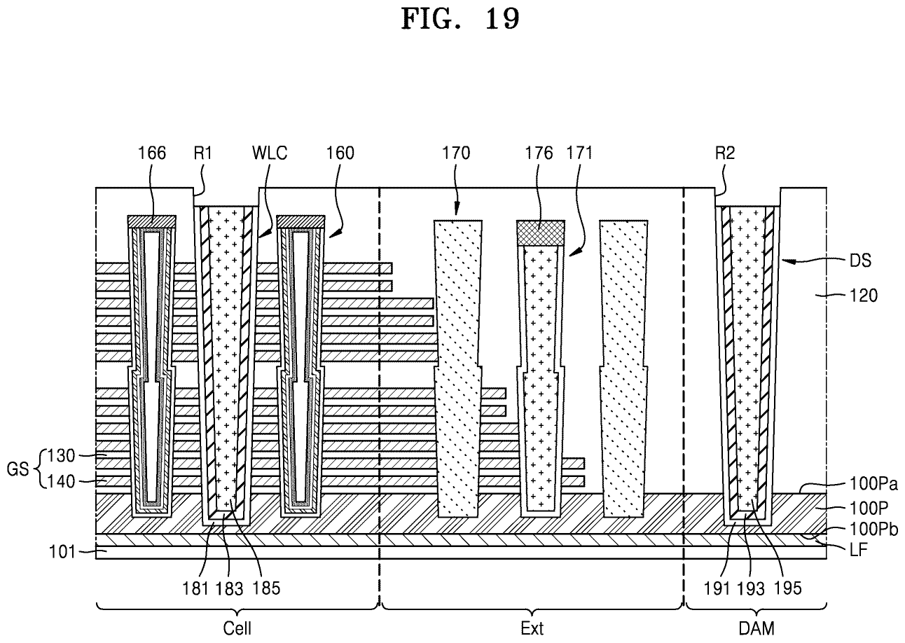

Referring to FIG. 19, a first recess R1 may be formed by partially etching the upper portions of the oxide film 181, the spacer liner 183, and the carbon layer 185 in the cell region CELL, and a second recess R2 may be formed by partially etching the upper portions of the dam oxide film 191, the spacer liner 183, and the carbon layer 185 similarly in the dam region DAM. According to embodiments, the depth of the first recess R1 and the depth of the second recess R2 in the Z direction may be substantially the same.

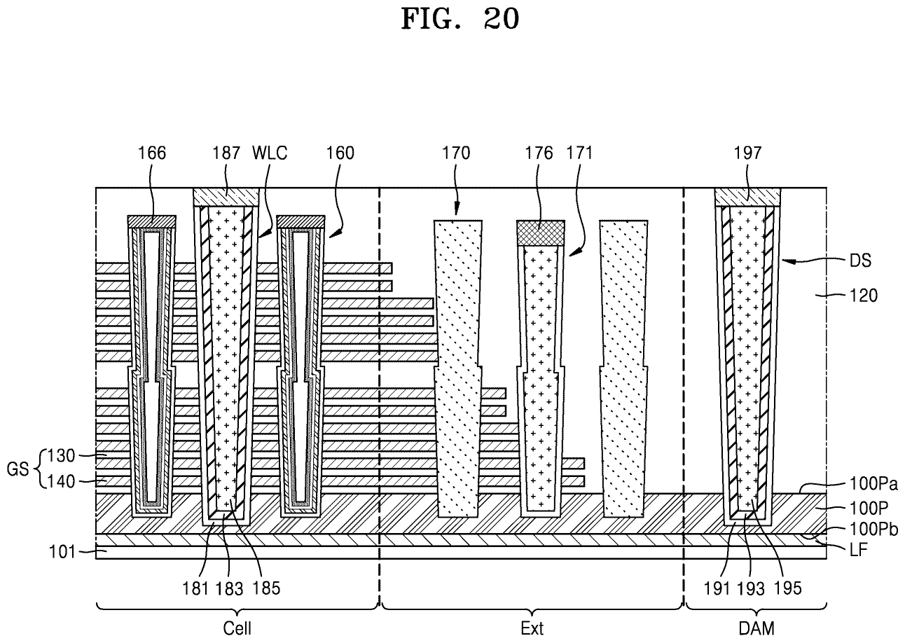

Referring to FIG. 20, the word line cut pad 187 may be formed in the first recess R1, and the dam structure pad 197 may be formed in the second recess R2. At this time, the top surfaces of the word line cut pad 187 and the dam structure pad 197 may be at the same vertical level as the top surface of the cover insulation layer 120 relative to the upper surface of the substrate 101 in the Z direction. According to embodiments, the constituent material of the word line cut pad 187 and the constituent material of the dam structure pad 197 may be substantially the same.

According to embodiments, the thickness of the first recess R1 in the Z direction may be from about 100 nm to about 1000 nm. In other words, the vertical thickness (or thickness in the Z direction) of the word line cut pad 187 may be from about 100 nm to about 1000 nm.

According to embodiments, the word line cut pad 187 and the dam structure pad 197 may include polysilicon. According to embodiments, the word line cut pad 187 and the dam structure pad 197 may include an oxide. According to embodiments, the word line cut pad 187 and the dam structure pad 197 may include silicon nitride (SIN).

After the process of FIG. 20 is completed, the method may return to FIG. 8 and the remaining processes may be performed as described above.

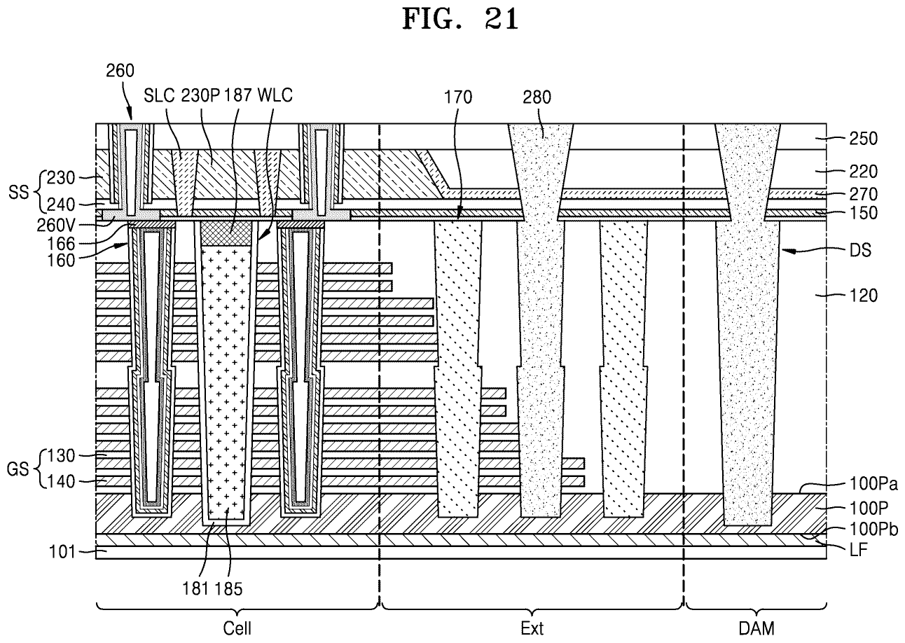

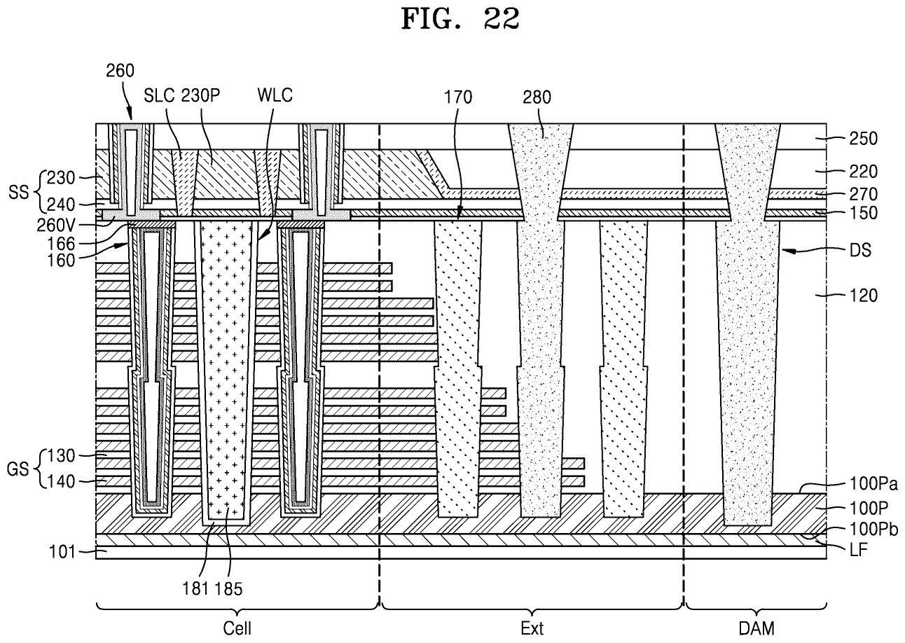

FIGS. 21 and 22 are cross-sectional views of non-volatile memory devices according to other embodiments.

Referring to FIG. 21, a non-volatile memory device has a configuration similar to that of the non-volatile memory device described above with reference to FIGS. 5 to 20. However, the non-volatile memory device of FIG. 21 does not include a spacer liner (e.g., the spacer liner 183) on the sidewall and the bottom surface of the word line cut WLC. Referring to the word line cut WLC of FIG. 21, the carbon layer 185 may be filled or provided directly on the oxide film 181 deposited on the sidewall of the word line cut WLC. Like the non-volatile memory device described above with reference to FIGS. 5 to 20, the carbon layer 185 may include only pure carbon (C). However, the present disclosure is not limited thereto, and the carbon layer 185 may include a C-containing material.

Referring to FIG. 22, a non-volatile memory device has a configuration similar to that of the non-volatile memory device described above with reference to FIGS. 5 to 20. However, the non-volatile memory device of FIG. 22 does not include a spacer liner (e.g., the spacer liner 183) on the sidewall and the bottom surface of the word line cut WLC, and no word line cut pad (e.g., the word line cut pad 187) is disposed over or on the word line cut WLC.

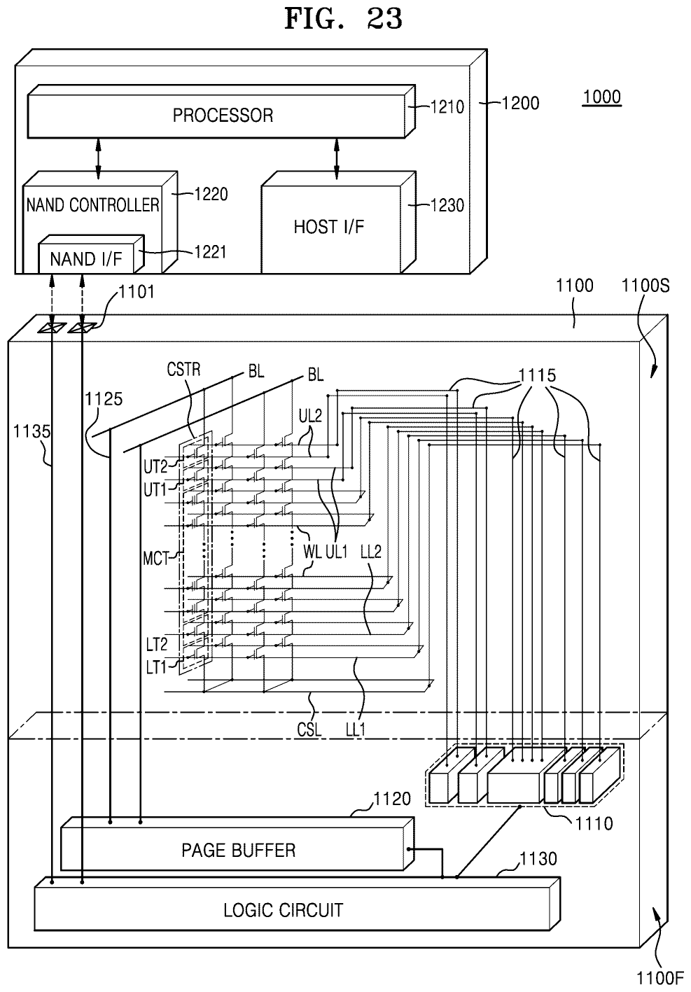

FIG. 23 is a configuration diagram showing an electronic system including a non-volatile memory device according to some embodiments.

Referring to FIG. 23, an electronic system 1000 according to the present disclosure may include a non-volatile memory device 1100 and a controller 1200 electrically connected to the non-volatile memory device 1100.

The electronic system 1000 may be a storage device including one or a plurality of non-volatile memory devices 1100 or an electronic device including the storage device. For example, the electronic system 1000 may be a solid state drive (SSD) device, a universal serial bus (USB), a computing system, a medical device, or a communication device including at least one non-volatile memory device 1100.

The non-volatile memory device 1100 may be a non-volatile vertical memory device. For example, the non-volatile memory device 1100 may be a NAND flash memory device that includes at least one of the non-volatile memory devices described above with reference to FIGS. 5 to 22. The non-volatile memory device 1100 may include a first structure 1100F and a second structure 1100S on the first structure 1100F. According to some embodiments, the first structure 1100F may also be disposed next to the second structure 1100S.

The first structure 110OF may be a peripheral circuit structure including a decoder circuit 1110, a page buffer 1120, and a logic circuit 1130. The second structure 1100S may be a memory cell structure including the bit lines BL, the common source line CSL, the plurality of word lines WL, first and second gate upper lines UL1 and UL2, first and second gate lower lines LL1 and LL2, and a plurality of memory cell strings CSTR between the bit lines BL and the common source line CSL.

In the second structure 1100S, the plurality of memory cell strings CSTR may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of lower transistors LT1 and LT2 and the number of upper transistors UT1 and UT2 may be variously changed according to embodiments.

According to some embodiments, the upper transistors UT1 and UT2 may include string select transistors and the lower transistors LT1 and LT2 may include ground select transistors. The first and second gate lower lines LL1 and LL2 may be gate layers of the lower transistors LT1 and LT2, respectively. The word line WL may be a gate layer of a memory cell transistor MCT, and the first and second gate upper lines L1 and UL2 may be gate layers of the upper transistors UT1 and UT2, respectively.

The common source line CSL, the first and second gate lower lines LL1 and LL2, the plurality of word lines WL, and the first and second gate upper lines UL1 and UL2 may be electrically connected to the decoder circuit 1110 through a plurality of first connection wires 1115 extending from the inside of the first structure 1100F to the second structure 1100S. The plurality of bit lines BL may be electrically connected to the page buffer 1120 through a plurality of second connection wires 1125 extending from the inside of the first structure 1100F to the second structure 1100S.

In the first structure 1100F, the decoder circuit 1110 and the page buffer 1120 may execute a control operation on at least one of the plurality of memory cell transistors MCT. The decoder circuit 1110 and the page buffer 1120 may be controlled by the logic circuit 1130.

The non-volatile memory device 1100 may communicate with the controller 1200 through an input/output pad 1101 electrically connected to the logic circuit 1130. The input/output pad 1101 may be electrically connected to the logic circuit 1130 through an input/output connection wire 1135 extending from the inside of the first structure 1100F to the second structure 1100S.

The controller 1200 may include a processor 1210, a NAND controller 1220, and a host interface 1230. In some embodiments, the electronic system 1000 may include a plurality of non-volatile memory devices 1100. In this case, the controller 1200 may control the plurality of non-volatile memory devices 1100.

The processor 1210 may control the overall operation of the electronic system 1000 including the controller 1200. The processor 1210 may operate according to a certain firmware and may access the non-volatile memory device 1100 by controlling the NAND controller 1220. The NAND controller 1220 may include a NAND interface 1221 that handles communication with the non-volatile memory device 1100. Control commands for controlling the non-volatile memory device 1100, data to be written to the memory cell transistors MCT of the non-volatile memory device 1100, and data to be read from the memory cell transistors MCT of the non-volatile memory device 1100 may be transmitted through the NAND interface 1221. The host interface 1230 may provide the function for communication between the electronic system 1000 and an external host. When a control command is received from an external host through the host interface 1230, the processor 1210 may control the non-volatile memory device 1100 in response to the control command.

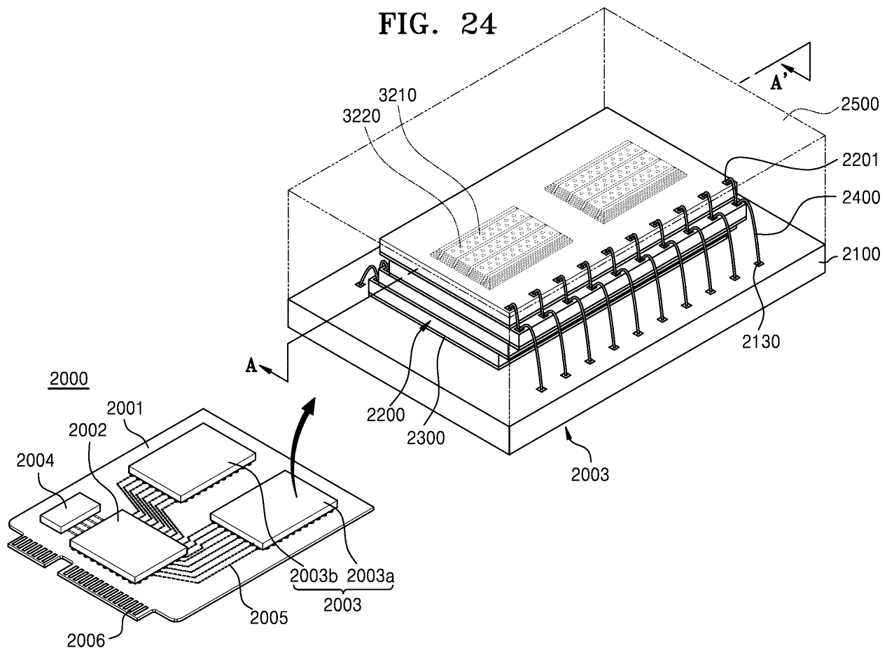

FIG. 24 is a perspective view of an electronic system including a non-volatile memory device according to some embodiments.

Referring to FIG. 24, an electronic system 2000 according to some embodiments may include a main substrate 2001 and a controller 2002, one or more semiconductor packages 2003, and dynamic random-access memory (DRAM) 2004 that are mounted on the main substrate 2001.

The main substrate 2001 may include a connector 2006 including a plurality of pins coupled to an external host. The number and arrangement of the pins of the connector 2006 may vary according to a communication interface between the electronic system 2000 and the external host. According to some embodiments, the electronic system 2000 may communicate with an external host according to any one of interfaces like USB, Peripheral Component Interconnect Express (PCI-Express), Serial Advanced Technology Attachment (SATA), M-Phy for Universal Flash Storage (UFS), etc. According to some embodiments, the electronic system 2000 may operate by power supplied from an external host through the connector 2006. The electronic system 2000 may further include a power management integrated circuit (PMIC) that distributes power supplied from the external host to the controller 2002 and the semiconductor package 2003. The semiconductor package 2003 and the DRAM 2004 may be connected to the controller 2002 by a plurality of wiring patterns 2005 formed on the main substrate 2001.

The controller 2002 may write data to or read data from the semiconductor package 2003 and may improve the operating speed of the electronic system 2000.

The DRAM 2004 may be a buffer memory for mitigating a speed difference between the semiconductor package 2003, which is a data storage space, and an external host. The DRAM 2004 included in the electronic system 2000 may also operate as a type of cache memory and may provide a space for temporarily storing data in a control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, the semiconductor chips 2200 on the package substrate 2100, an adhesive layer 2300 disposed on the bottom surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including a plurality of package upper pads 2130. The semiconductor chips 2200 may each include an input/output pad 2201. The input/output pad 2201 may correspond to the input/output pad 1101 of FIG. 24. The plurality of semiconductor chips 2200 may each include a plurality of gate stacks 3210 and a plurality of channel structures 3220. The semiconductor chips 2200 may each include at least one of non-volatile memory devices described with reference to FIGS. 5 to 22.

According to embodiments, the connection structure 2400 may be a bonding wire electrically connecting the input/output pad 2201 and the package upper pad 2130. Therefore, in the first and second semiconductor packages 2003a and 2003b, the semiconductor chips 2200 may be electrically connected to one another through bonding wires and may be electrically connected to the package upper pads 2130 of the package substrate 2100. According to some embodiments, in the first and second semiconductor packages 2003a and 2003b, the semiconductor chips 2200 may be connected to one another through a connection structure including through silicon vias (TSVs) instead of the connection structure 2400 including bonding wires.

According to some embodiments, the memory controller 2002 and the semiconductor chips 2200 may be included in one package. According to some embodiment, the controller 2002 and the semiconductor chips 2200 may be mounted on a separate interposer substrate different from the main substrate 2001 and the controller 2002 and the semiconductor chips 2200 may be connected to each other through wires formed on the interposer substrate.

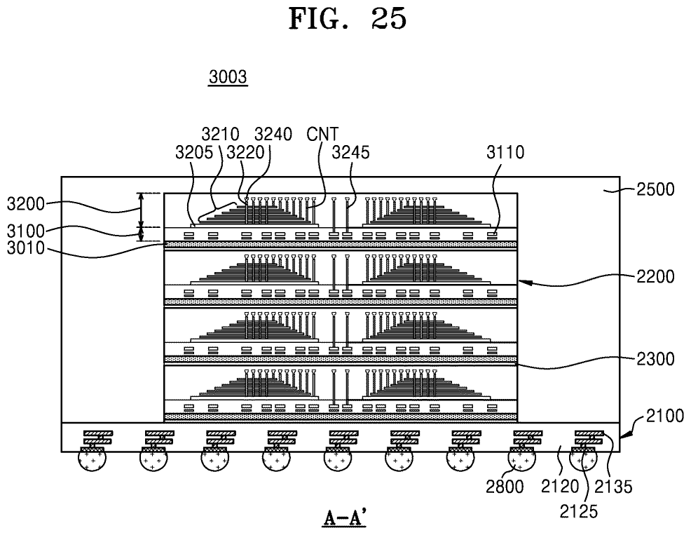

FIG. 25 is a cross-sectional view of a semiconductor package including a non-volatile memory device according to some embodiments. In detail, FIG. 25 is a detailed cross-sectional view taken along a line A-A′ of FIG. 24.

Referring to FIG. 25, in a semiconductor package 3003, the package substrate 2100 may be a printed circuit board.

The package substrate 2100 may include a body 2120, a plurality of upper pads 2130 (refer to FIG. 24) arranged on the top surface of the body 2120, and a plurality of lower pads 2125 arranged or exposed on the bottom surface of the body 2120, and a plurality of internal wires 2135 electrically interconnecting the plurality of upper pads 2130 and the plurality of lower pads 2125 inside the body 2120. The plurality of upper pads 2130 may be electrically connected to a plurality of connection structures 2400 (refer to FIG. 24). The plurality of lower pads 2125 may be connected to the plurality of wiring patterns 2005 on the main substrate 2001 of the memory system 2000 shown in FIG. 24 through a plurality of conductive connections 2800.

The plurality of semiconductor chips 2200 may each include a semiconductor substrate 3010 and a first structure 3100 and a second structure 3200 sequentially stacked on the semiconductor substrate 3010. The first structure 3100 may include a peripheral circuit region including a plurality of peripheral wires 3110. The second structure 3200 may include a common source line 3205, a gate stack 3210 on the common source line 3205, a channel structure 3220 penetrating through the gate stack 3210, and a bit line 3240 electrically connected to the channel structure 3220.

The plurality of semiconductor chips 2200 may each include a through wire 3245 electrically connected to the plurality of peripheral wires 3110 of the first structure 3100 and extending into the second structure 3200. The through wire 3245 may be disposed outside the gate stack 3210. According to other embodiments, the semiconductor package 3003 may further include a through wire penetrating through the gate stack 3210. The plurality of semiconductor chips 2200 may each further include the input/output pad 2201 (refer to FIG. 24) electrically connected to the plurality of peripheral wires 3110 of the first structure 3100.

While the present disclosure has been particularly shown and described with reference to embodiments thereof, it will be understood that various changes in form and details may be made therein without departing from the spirit and scope of the following claims.

What is claimed is:

1. A non-volatile memory device comprising:
a semiconductor substrate comprising a cell region, a dam region surrounding at least a portion of the cell region, and a stepped region between the cell region and the dam region;
a gate stack comprising a plurality of word line gate layers and a plurality of insulation layers that extend in a first direction that is parallel to an upper surface of the semiconductor substrate and are alternately stacked in a second direction that is perpendicular to the upper surface of the semiconductor substrate, wherein the gate stack has a stepped shape on the stepped region;
a plurality of first channel structures that are on the cell region and extend into the gate stack in the second direction;
a dummy channel structure that is on the stepped region and extends into the gate stack and in the second direction;
a word line cut that is on the cell region and extends into the gate stack in the second direction;
at least one string select line on the gate stack;
a plurality of second channel structures that extend into the at least one string select line from the plurality of first channel structures in the second direction;
a string select line cut that extends into the at least one string select line gate in the second direction;
a buried structure that is on the stepped region and extends in the second direction;
a dam structure that is on the dam region and extends in the second direction;
an oxide film that is on a sidewall of the word line cut and a bottom surface of the word line cut;
a spacer liner that at least partially overlaps the oxide film in the first direction and the second direction; and
a carbon layer that at least partially overlaps the spacer liner in the first direction and the second direction.

2. The non-volatile memory device of claim 1, wherein the spacer liner comprises at least one of polysilicon, titanium nitride, or tungsten.

3. The non-volatile memory device of claim 1, wherein a thickness of the spacer liner in the second direction is at least 15 nm.

4. The non-volatile memory device of claim 1, wherein a thickness of the spacer liner in the second direction is less than or equal to 50 nm.

5. The non-volatile memory device of claim 1, wherein the carbon layer only comprises carbon.

6. The non-volatile memory device of claim 1, wherein the word line cut further comprises a word line cut pad that at least partially overlaps a top end of the word line cut in the second direction.

7. The non-volatile memory device of claim 6, wherein a thickness of the word line cut pad in the second direction is between about 100 nm to about 1000 nm.

8. The non-volatile memory device of claim 6, wherein the word line cut pad comprises at least one of polysilicon, oxide, or silicon nitride.

9. The non-volatile memory device of claim 1, wherein relative to the upper surface of the semiconductor substrate in the second direction, a first height of the buried structure and a second height of the dam structure are equal to a third height of a top surface of each of the second channel structures that are on the cell region.

10. The non-volatile memory device of claim 1, wherein the buried structure and the dam structure comprise a substantially same material.

11. The non-volatile memory device of claim 1, wherein a width of a top end of the buried structure in the first direction and a width of a top end of the dam structure are greater than a width of a bottom end of the buried structure in the first direction and a width of a bottom end of the dam structure in the first direction, respectively.

12. The non-volatile memory device of claim 1, wherein a level of a top end of the word line cut relative to the upper surface of the semiconductor substrate in the second direction is substantially identical to a level of a top end of each of the plurality of first channel structures relative to the upper surface of the semiconductor substrate in the second direction.

13. The non-volatile memory device of claim 1, wherein a first one of the plurality of first channel structures and a first one of the plurality of second channel structures are electrically connected to each other through a connection via.

14. A non-volatile memory device, comprising:
a semiconductor substrate comprising a cell region, a stepped region adjacent to the cell region and having a stepped shape, and a dam region surrounding at least a portion of the cell region and the stepped region,
a gate stack on the cell region;
a plurality of first channel structures that extend into the gate stack in a first direction that is perpendicular to an upper surface of the semiconductor substrate;
a word line cut that extends into the gate stack and extends in the first direction;
at least one string select line on the gate stack;
a plurality of second channel structures that extend into the at least one string select line from the plurality of first channel structures and extend in the first direction;
a string select line cut that extends into the at least one string select line and extends in a second direction that is parallel to the upper surface of the semiconductor substrate;
a dummy channel structure that is on the stepped region and extends in the first direction;
a buried structure that is spaced apart from the dummy channel structure in the second direction and extends in the first direction;
a dam structure that is on the dam region and extends in the second direction;
an oxide film on sidewalls of the word line cut and a bottom surface of the word line cut; and
a carbon layer that comprises carbon (C) and at least partially overlaps the oxide film in the first direction and the second direction.

15. The non-volatile memory device of claim 14, wherein the word line cut further comprises a word line cut pad that at least partially overlaps a top end of the word line cut in the first direction and has a thickness between about 100 nm to about 1000 nm in the first direction.

16. The non-volatile memory device of claim 15, wherein the word line cut pad comprises at least one of polysilicon, oxide, or silicon nitride.

17. The non-volatile memory device of claim 14, wherein the buried structure and the dam structure comprise a substantially same material.

18. The non-volatile memory device of claim 14, wherein relative to the upper surface of the semiconductor substrate in the first direction, a first height of the buried structure and a second height of the dam structure extend are greater than a third height of a top end of the word line cut.

19. A non-volatile memory device comprising:
a semiconductor substrate comprising a cell region, a stepped region adjacent to the cell region, and a dam region surrounding the cell region and the stepped region;
a gate stack that is on the cell region and the stepped region and extends in a first direction that is parallel to a main surface of the semiconductor substrate, wherein the gate stack has a stepped shape on the stepped region;
a plurality of first channel structures that are on the cell region and extend into the gate stack in a second direction that is perpendicular to the main surface of the semiconductor substrate;
a word line cut that is spaced apart from the plurality of first channel structures in the first direction and extends in parallel with the plurality of first channel structures in the second direction;
at least one string select line on the gate stack;
a plurality of second channel structures that extend into the at least one string select line from the plurality of first channel structures in the second direction;
a string select line cut that extends into the at least one string select line in the first direction;
a dummy channel structure and a buried structure that extend into the gate stack on the stepped region in the second direction;
a dam structure that extends in the second direction and is on the dam region;
an oxide film that is on a sidewall of the word line cute and a bottom surface of the word line cut; and
a carbon layer that is on the oxide film and in the word line cut,
wherein the buried structure and the dam structure comprise a substantially same material, and
wherein, relative to the main surface of the semiconductor substrate in the second direction, a first height of the buried structure and a second height of the dam structure are greater than a third height of the word line cut.

20. The non-volatile memory device of claim 19, further comprising a spacer liner between the oxide film and the carbon layer, wherein:
the spacer liner is on a top surface of the oxide film and has a thickness between about 15 nm to about 50 nm in the first direction or the second direction, and
the spacer liner comprises at least one of polysilicon, titanium nitride, or tungsten.
